(19) United States
(12) Patent Application Publication
(10) Pub. No.: US 2025/0247113 A1
(43) Pub. Date: Jul. 31, 2025

(54) MODEM CHIP FOR LOW-POWER DECODING BASED ON TRANSITION OF LOG LIKELIHOOD RATIO AND OPERATING METHOD OF TURBO DECODER

(71) Applicant: SAMSUNG ELECTRONICS CO., LTD., Suwon-si (KR)

(72) Inventors: Joohan KIM, Suwon-si (KR); Suhwang JEONG, Suwon-si (KR); Youngseok JUNG, Suwon-si (KR)

(73) Assignee: SAMSUNG ELECTRONICS CO., LTD., Suwon-si (KR)

(21) Appl. No.: 18/975,826

(22) Filed: Dec. 10, 2024

(30) Foreign Application Priority Data
Jan. 26, 2024 (KR) 10-2024-0012665

(51) Int. Cl. H03M 13/29; H03M 13/39; H04L 1/00

(52) U.S. Cl. CPC H03M 13/2957; H03M 13/3927; H04L 1/0047

(57) ABSTRACT

A modem chip may include a turbo decoding circuit configured to receive a plurality of channel log likelihood ratios respectively corresponding to a plurality of bits included in a symbol, generate a plurality of first posteriori log likelihood ratios respectively corresponding to the plurality of bits in an N^{th} iterative loop based on the plurality of channel log likelihood ratios, wherein N is greater than or equals to 1, and generate a first input/output counting value by counting a number of first posteriori log likelihood ratios, among the plurality of first posteriori log likelihood ratios, that differ in sign from the corresponding channel log-likelihood ratios, and a decoding control circuit configured to stop decoding for the plurality of bits in the turbo decoding circuit based on the first input/output counting value being greater than or equal to a first threshold.

### CROSS-REFERENCE TO RELATED APPLICATION

This application is based on and claims priority under 35 U.S.C. § 119 to Korean Patent Application No. 10-2024-0012665, filed on Jan. 26, 2024, in the Korean Intellectual Property Office, the disclosure of which is incorporated by reference herein in its entirety.

### BACKGROUND

Apparatuses and methods consistent with one or more embodiments relate to a receiver and an operating method of the receiver, and more particularly, to a modem chip including a turbo decoder for reducing power consumed in decoding based on transitions of log likelihood ratios and an operating method of the turbo decoder.

Recently, as wired and wireless communication technologies and smart device-related technologies have developed rapidly, there is a growing need for a method that enables low-power decoding with high decoding accuracy for signals received by a receiver in a wireless communication system.

Generally, a receiver can receive an encoded signal from a transmitter, decode the received signal, and obtain information transmitted by the transmitter. The receiver may repeatedly generate log likelihood ratios to decode the received signal. When decoding is performed properly, signs of a plurality of log likelihood ratios respectively corresponding to bits may be the same. On the other hand, when decoding is not properly performed, signs of a plurality of log likelihood ratios respectively corresponding to bits may be different from each other. Accordingly, when the signs of the plurality of corresponding log likelihood ratios are different, the receiver may fail to decode the plurality of bits. Therefore, when a decoding failure is expected, that is, i.e., when the signs of the log likelihood ratios are different, a method of stopping decoding early before a predetermined number of times is required to reduce power consumption.

### SUMMARY

One or more example embodiments provide a modem chip capable of performing low-power decoding based on sign transitions of log likelihood ratios and an operating method of a turbo decoder.

According to an aspect of the present disclosure, a modem chip may include: a turbo decoding circuit configured to: receive a plurality of channel log likelihood ratios respectively corresponding to a plurality of bits included in a symbol; generate a plurality of first posteriori log likelihood ratios respectively corresponding to the plurality of bits in an N^{th} iterative loop based on the plurality of channel log likelihood ratios, wherein N is greater than or equals to 1; and generate a first input/output counting value by counting a number of first posteriori log likelihood ratios, among the plurality of first posteriori log likelihood ratios, that differ in sign from the corresponding channel log-likelihood ratios; and a decoding control circuit configured to stop decoding for the plurality of bits in the turbo decoding circuit based on the first input/output counting value being greater than or equal to a first threshold.

According to an aspect of the present disclosure, a modem chip may include: a turbo decoding circuit configured to: receive a plurality of channel log likelihood ratios respectively corresponding to a plurality of bits included in a symbol; generate a plurality of first extrinsic log likelihood ratios respectively corresponding to the plurality of bits in an N^{th} iterative loop based on the plurality of channel log likelihood ratios, wherein N is greater than or equals to 1; generate a plurality of second extrinsic log likelihood ratios respectively corresponding to the plurality of bits in an N+1^{th} iterative loop; and generate a first extrinsic counting value by counting a number of second extrinsic log likelihood ratios, among the plurality of second extrinsic log likelihood ratios, that differ in sign from the corresponding first extrinsic log likelihood ratios; and a decoding control circuit configured to stop decoding for the plurality of bits in the turbo decoding circuit based on the first extrinsic counting value being greater than or equal to a first threshold.

According to an aspect of the present disclosure, an operating method of a turbo decoder may include: receiving a plurality of bits included in a symbol; generating a plurality of channel log likelihood ratios respectively corresponding to the plurality of bits; generating at least one log likelihood ratio respectively corresponding to the plurality of bits based on the plurality of channel log likelihood ratios; generating a counting value by counting a number of bits, among the plurality of bits, where two corresponding log likelihood ratios have different signs; and stopping decoding for the plurality of bits based on the counting value being greater than or equal to a preset threshold, wherein the two different log likelihood ratios may include the at least one log likelihood ratio.

### BRIEF DESCRIPTION OF THE DRAWINGS

Embodiments will be more clearly understood from the following detailed description taken in conjunction with the accompanying drawings in which:

FIG. 1 is a block diagram of a communication system according to one or more embodiments;

FIG. 2 is a block diagram of a transmitter;

FIG. 3 is a block diagram of a receiver according to one or more embodiments;

FIGS. 4A to 4C are block diagrams of a turbo decoder according to one or more embodiments;

FIG. 5 is a block diagram of an extrinsic sign comparator according to one or more embodiments;

FIG. 6 is a table showing sign transitions of an extrinsic log likelihood ratio according to one or more embodiments;

FIGS. 7A and 7B are block diagrams of a turbo decoder according to one or more embodiments;

FIG. 8 is a table showing a sign transition of a posteriori log likelihood ratio with respect to a sign of a channel log likelihood ratio according to one or more embodiments;

FIG. 9 is a block diagram of a turbo decoder according to one or more embodiments;

FIG. 10 is a flowchart of an operating method of a turbo decoder according to one or more embodiments; and

FIG. 11 is a block diagram of a wireless communication device according to one or more embodiments.

### DETAILED DESCRIPTION OF THE EMBODIMENTS

Example embodiments are described in greater detail below with reference to the accompanying drawings.

In the following description, like drawing reference numerals are used for like elements, even in different drawings. The matters defined in the description, such as detailed construction and elements, are provided to assist in a comprehensive understanding of the example embodiments. However, it is apparent that the example embodiments can be practiced without those specifically defined matters. Also, well-known functions or constructions are not described in detail since they would obscure the description with unnecessary detail.

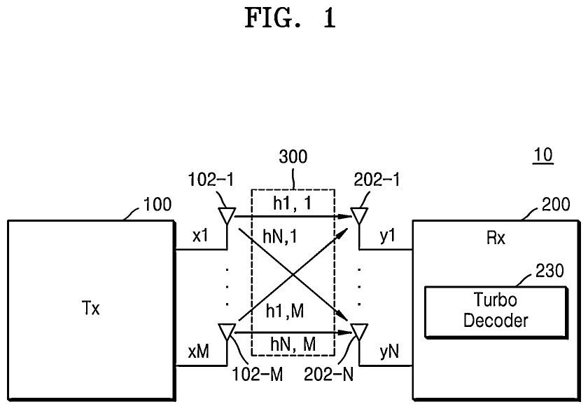

FIG. 1 is a block diagram of a communication system according to one or more embodiments. Referring to FIG. 1, a communication system 10 may include a transmitter 100 and a receiver 200 that communicate wirelessly through a multi-input multi-output (MIMO) channel 300.

The communication system 10 may be any system that includes the MIMO channel 300. In some embodiments, the communication system 10 may include, but not limited to, a wireless communication system, such as a 5th generation (5G) wireless system, a long-term evolution (LTE) system, and WiFi. In some embodiments, the communication system 10 may include a wired communication system, such as a storage system, a network system, and the like. Hereinafter, the communication system 10 is described primarily as a wireless communication system but is limited thereto.

For example, the transmitter 100 may be a base station or a component included in the base station. The base station may refer to a fixed station that communicates with terminals and/or other base stations and may transmit/receive data and/or control information by communicating with the terminals and/or the other base stations. The base station may be referred to as a Node B, an evolved-Node B (eNB), a base transceiver system (BTS), and an access point (AP).

For example, the receiver 200 may be a terminal or a component provided in the terminal. The terminal, which is a wireless communication device, may refer to various devices capable of transmitting/receiving data and/or control information by communicating with the transmitter 100. For example, the terminal may be referred to as user equipment, a mobile station (MS), a mobile terminal (MT), a user terminal (UT), a subscribe station (SS), a wireless device, a portable device, and the like.

A wireless communication network between the transmitter 100 and the receiver 200 may support communication between multiple users by sharing available network resources. For example, in the wireless communication network, information may be transmitted in various ways, such as code division multiple access (CDMA), frequency division multiple access (FDMA), time division multiple access (TDMA), orthogonal frequency division multiple access (OFDMA), single carrier frequency division multiple access (SC-FDMA), and the like.

The transmitter 100 may be provided with a plurality of transmit antennas 102-1 to 102-M (hereinafter, M is a positive integer) and may transmit symbols x1 to xM through the plurality of transmit antennas 102-1 to 102-M, respectively. In addition, the receiver 200 may be provided with a plurality of receive antennas 202-1 to 202-N (hereinafter, N is a positive integer) and may receive a plurality of symbols y1 to yN through the plurality of receive antennas 202-1 to 202-N, respectively.

For example, a symbol vector “x” transmitted from the transmitter 100 is denoted by x=[x1, . . . xM]^{T}, and a symbol vector “y” received by the receiver 200 may be expressed as Equation 1 below.

$$y = Hx + n = ( \begin{matrix}h 1 , 1 & … & h 1 , M \\ ⋮ & ⋱ & ⋮ \\ hN , 1 & … & hN , M\end{matrix} ) ( \begin{matrix}x 1 \\ ⋮ \\ xM\end{matrix} ) + ( \begin{matrix}n 1 \\ ⋮ \\ nN\end{matrix} ) \qquad [ Equation 1 ]$$

In Equation 1, hi,j may represent an effective channel gain between j^{th} (j is an integer from 1 to M) transmit antenna and i^{th} (i is an integer from 1 to N) receive antenna, and xj may represent a transmitted symbol from the j^{th} transmit antenna (or transmit layer).

The transmitted symbol xj may be one of constellation points. The constellation point may refer to a point on a complex plane used by the transmitter 100 to map a transmitted signal. The number and location of the constellation points on the complex plane may vary depending on a method of modulating the transmitted signal. For example, when the transmitter 100 modulates the transmitted signal using a quadrature phase shift keying (QPSK) method, one constellation point may be located in each quadrant of the complex plane. That is, four constellation points may be used to modulate the transmitted signal. The transmitter 100, which modulates the transmitted signal using the QPSK method, may map the transmitted signal to one of the four constellation points and transmit the same to the receiver 200. However, the modulation method of the transmitter 100 is not limited thereto. It may be easily understood that the transmitted signal is modulated by using 16QAM, 64QAM, 256QAM, and 1024QAM methods.

Additionally, in Equation 1, ni represents additive white Gaussian noise (AWGN) from the i^{th} receive antenna, and ni may have power (or variance) of σ². The AWGN may also include an interference signal. In the communication system 10, noise from the receive antenna may be considered along with the influence of the interference signal. However, hereinafter, it is assumed that the power of AWGN for each receive antenna is the same and is not spatially correlated.

The receiver 200 may include a turbo decoder 230 for decoding a plurality of bits. The turbo decoder 230 may generate a log likelihood ratio (LLR) for each of the plurality of bits based on similarities between a plurality of candidate points and the received signal. For example, the turbo decoder 230 may calculate an Euclidean distance between a plurality of candidate points and the received signal and may calculate the log likelihood ratio based on the Euclidean distance. The plurality of candidate points may be determined according to the modulation method of the transmitter 100. For example, when the transmitter 100 modulates a transmitted signal using the QPSK method and a symbol is transmitted from two transmit antennas to one receive antenna, there may be 16 candidate points. The turbo decoder 230 may calculate the log likelihood ratio based on the Euclidean distance between the plurality of candidate points and the received symbol. For example, when the Euclidean distance between candidate points corresponding to 0 among the plurality of candidate points and the received symbol is less than the Euclidean distance between candidate points corresponding to 1 among the plurality of candidate points and the received symbol, the log likelihood ratio may be negative.

The receiver 200 may decode the corresponding bit based on the log likelihood ratio. As described above, when the log likelihood ratio is negative, the corresponding bit may be decoded as “0” among “1” and “0”. When the log likelihood ratio is positive, the corresponding bit may be decoded as “1” among “1” and “0”. However, this is only an example, and the one or more embodiments is not limited thereto. The log likelihood ratio may refer to a soft value indicating the probability that the received signal will be decoded as “0” or “1”. Thus, the turbo decoder 230 may iteratively refine the log likelihood ratio by decoding the received signal through multiple iterative loops, until the log likelihood ratio falls below a preset threshold, indicating a confident decoding decision based on the last generated log likelihood ratio. The turbo decoder 230 may decode the received signal based on the last generated log likelihood ratio. The log likelihood ratio according to the embodiment may be considered as a general term including a channel log likelihood ratio (channel LLR), a posteriori log likelihood ratio (posteriori LLR), a priori log likelihood ratio (priori LLR), and an extrinsic log likelihood ratio (extrinsic LLR). More details regarding the turbo decoder 230 and the log likelihood ratio are described below.

The receiver 200 according to one or more embodiments may generate an extrinsic counting value by counting the number of bits, among the plurality of bits included in the symbol, where a sign of a first extrinsic LLR generated in the N^{th} (hereinafter, N is an integer of 1 or greater and is independent of the number of antennas in the receiver 200) iterative loop is different from a sign of a second extrinsic LLR generated in the N+1^{th} iterative loop and may determine whether to stop decoding early based on the extrinsic counting value. Thus, when a decoding failure is expected based on the extrinsic counting value, the receiver 200 may reduce power consumed in decoding by stopping the decoding early. Herein, the counting value includes an extrinsic counting value and an input/output counting value to be described below. Details in this regard are described below.

The receiver 200 according to one or more embodiments may generate an input/output value by counting the number of bits, among the plurality of bits included in the symbol, where a sign of a corresponding channel LLR is different from a sign of a corresponding posteriori LLR and may determine whether to stop decoding early based on the input/output counting value. Thus, when a decoding failure is expected based on the input/output counting value, the receiver 200 may reduce power consumed in decoding by stopping the decoding early.

The receiver 200 according to another embodiment may determine whether to stop decoding early based on the aforementioned extrinsic counting value and input/output counting value. Thus, when a decoding failure is expected based on the input/output counting value, the receiver 200 may reduce power consumed in decoding by stopping the decoding early.

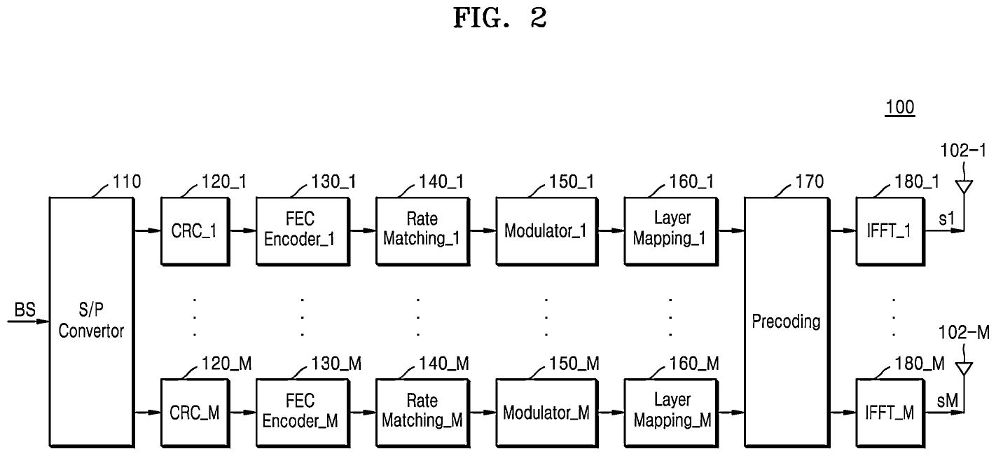

FIG. 2 is a block diagram of a transmitter according to one or more embodiments of the present disclosure.

FIG. 2 may show, for example, components included in the transmitter 100 of FIG. 1.

Referring to FIG. 2, the transmitter 100 may include a serial to parallel (S/P) converter 110, a plurality of cyclic redundancy check (CRC) units 120_1 to 120_M, a plurality of forward error correction (FEC) encoders 130_1 to 130_M, a plurality of rate matching units 140_1 to 140_M, a plurality of modulators 150_1 to 150_M, a plurality of layer mapping units 160_1 to 160_M, a precoding unit 170, a plurality of inverse fast Fourier transform (IFFT) units 180_1 to 180_M, and a plurality of antennas 102-1 to 102-M.

First, an information bit stream BS to be transmitted may be input to the S/P converter 110. The S/P converter 110 may generate a plurality of information bit streams by parallel converting the input information bit stream BS and may output the same to the CRC units 120_1 to 120_M, respectively. For example, the S/P converter 110 may parallel convert and output the information bit stream BS into a codeword (or transport block), which is a channel decoding input unit.

Each of the plurality of CRC units 120_1 to 120_M may perform a CRC operation on the parallel converted information bit streams and may output a signal on which the CRC operation has been performed to each of the FEC encoders 130_1 to 130_M. For example, the plurality of CRC units 120_1 to 120_M may perform the CRC operation to detect errors occurring during transmission.

The plurality of FEC encoders 130_1 to 130_M may use FEC techniques, utilizing an error correction code to correct errors caused by noise in signals received from the plurality of CRC units 120_1 to 120_M. For example, in a wireless communication system, a FEC method such as a convolution code, a turbo code, a low-density parity-check (LDPC) code, and a polar code may be used. The wireless communication system according to the one or more embodiments is described below on the assumption that a turbo code is used.

The plurality of rate matching units 140_1 to 140_M may perform a rate matching operation based on a preset rate matching method on signals output from the plurality of FEC encoders 130_1 to 130_M and may output the signals on which the rate matching operation has been performed to the plurality of modulators 150_1 to 150_M. Through the rate matching operation, the plurality of rate matching units 140_1 to 140_M may match the encoded bits with the number of modulation symbols assigned to a user.

The plurality of modulators 150_1 to 150_M may perform a modulation operation on the rate-matched signals based on a preset modulation method and may output the signals on which the modulation operation has been performed to the plurality of layer mapping units 160_1 to 160_M. For example, the plurality of modulators 150_1 to 150_M may map the rate-matched signals to constellation points. The plurality of layer mapping units 160_1 to 160_M may distribute the modulated signals to match the number of input layers of the precoding unit 170.

The precoding unit 170 may perform a precoding operation on the signals output from the layer mapping units 160_1 to 160_M, respectively, based on a preset precoding method and may output the same to the IFFT units 180_1 to 180_M. For example, the precoding method may be generated based on feedback information received by the transmitter 100. The plurality of IFFT units 180_1 to 180_M may convert a transmitted signal for each transmit antenna of a frequency domain output from the precoding unit 170 into a time domain through IFFT and may transmit the converted, transmitted signals s1 to sM to the antennas 102-1 to 102-M.

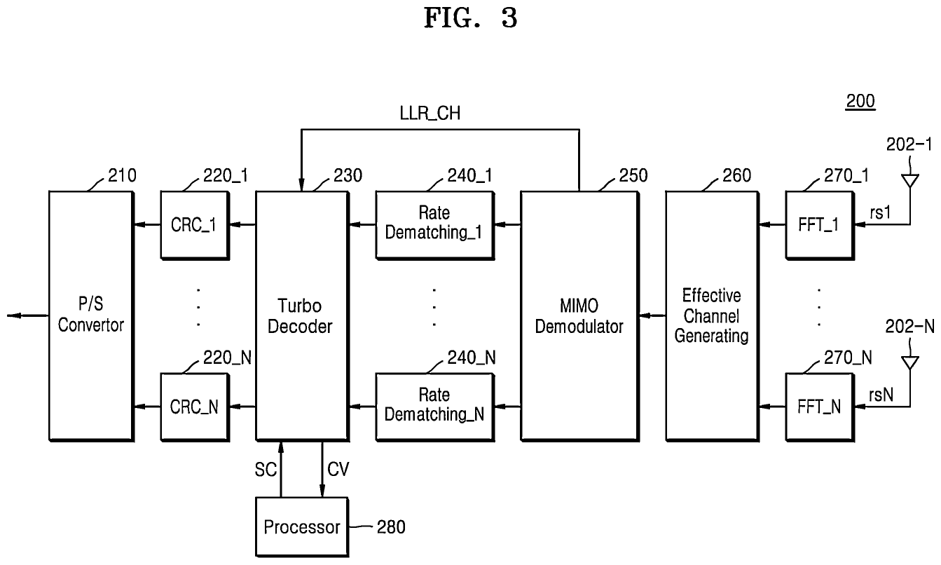

FIG. 3 is a block diagram of a receiver according to one or more embodiments.

FIG. 3 may show, for example, components included in the receiver 200 of FIG. 1.

Referring to FIG. 3, the receiver 200 may include a plurality of antennas 202-1 to 202-N, a plurality of fast Fourier transform (FFT) units 270_1 to 270_N, an effective channel generating unit 260, a MIMO demodulator 250, a plurality of rate dematching units 240_1 to 240_N, a turbo decoder 230, a plurality of CRC units 220_1 to 220_N, a parallel to serial (P/S) converter 210, and a processor 280.

The signals rs1 to rsN received through the plurality of antennas 202-1 to 202-N may be input to the plurality of FFT units 270_1 to 270_N, respectively. The plurality of FFT units 270_1 to 270_N may perform an FFT operation on the signals rs1 to rsN. That is, the plurality of FFT units 270_1 to 270_N may convert the time-domain signal received by each antenna into the frequency domain through FFT and may transmit the converted signals in the frequency domain to the effective channel generating unit 260.

The effective channel generating unit 260 may reflect the influence of the precoding method applied by the transmitter 100 to the received signals rs1 to rsM converted to the frequency domain and may output the same to the MIMO demodulator 250.

The MIMO demodulator 250 may perform a demodulation operation on the signals output from the effective channel generating unit 260 based on a demodulation method corresponding to the modulation method used in the transmitter 100. The MIMO demodulator 250 may generate a channel LLR LLR_CH using the received signals rs1 to rsN and the effective channel generated from the effective channel generating unit 260. The MIMO demodulator 250 may generate a plurality of channel LLRs LLR_CH corresponding to a plurality of bits, respectively, and may provide the same to the turbo decoder 230.

The plurality of rate dematching units 240_1 to 240_N may perform a rate dematching operation on the signals output from the MIMO demodulator 250 based on a rate dematching method corresponding to the rate matching method used in the transmitter 100.

The turbo decoder 230 may perform a decoding operation on the signals output from the plurality of rate dematching units 240_1 to 240_N based on an FEC decoding method corresponding the FEC encoding method used in the transmitter 100, described with reference to FIG. 2.

The plurality of CRC units 220_1 to 220_N may perform a CRC operation on the signals output from the turbo decoder 230 and may output the signals on which the CRC operation has been performed to the P/S converter 210. The P/S converter 210 may convert the signals, which are output from the plurality of CRC units 220_1 to 220_N in parallel, into a serial signal and then proceed to output the same.

The turbo decoder 230 may decode the received signals in units of code blocks including a plurality of bits. The turbo decoder 230 may perform decoding based on a plurality of extrinsic LLRs corresponding to the plurality of bits, respectively, included in the code block.

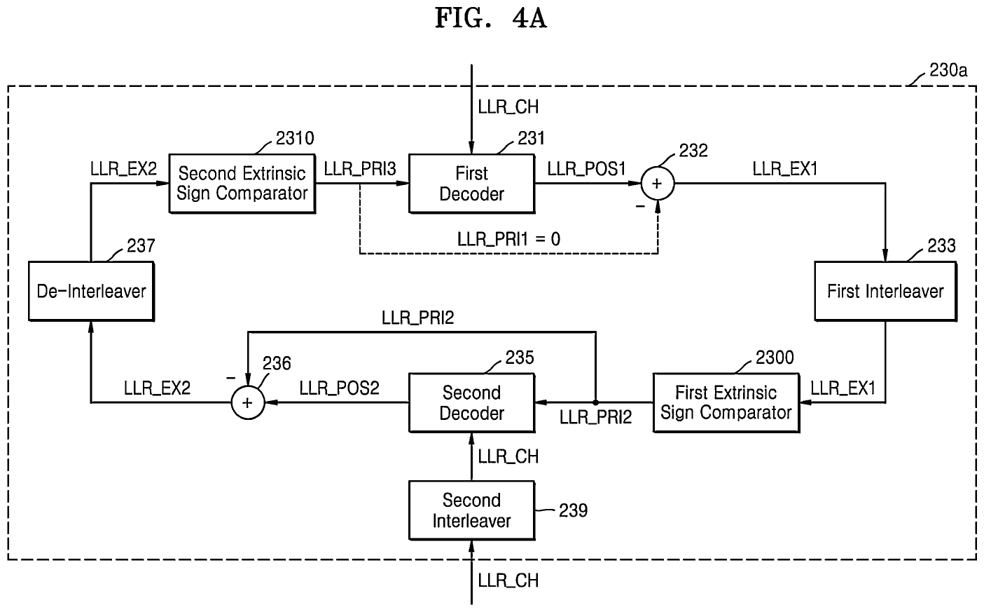

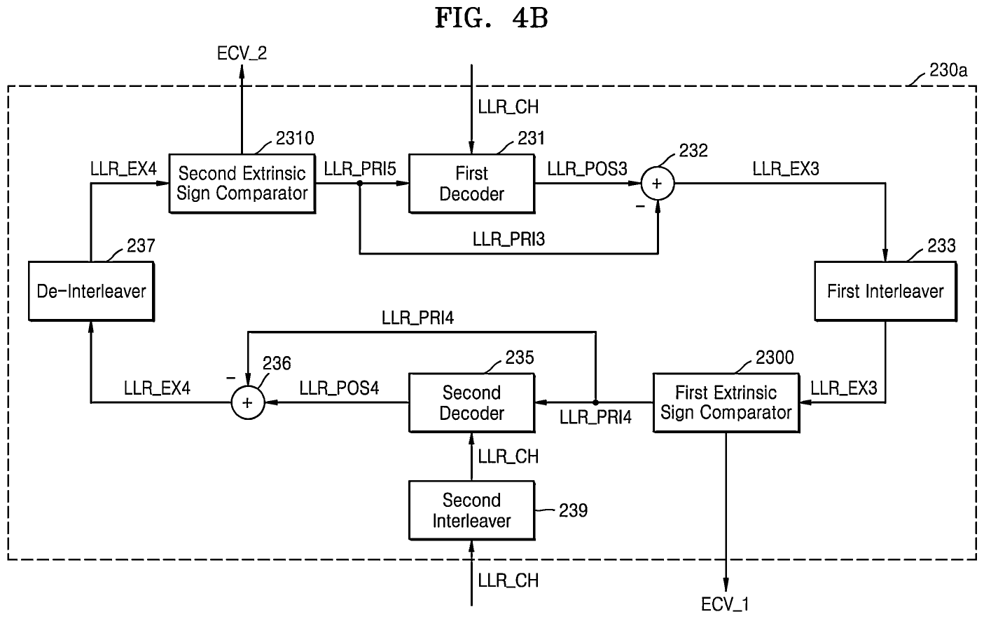

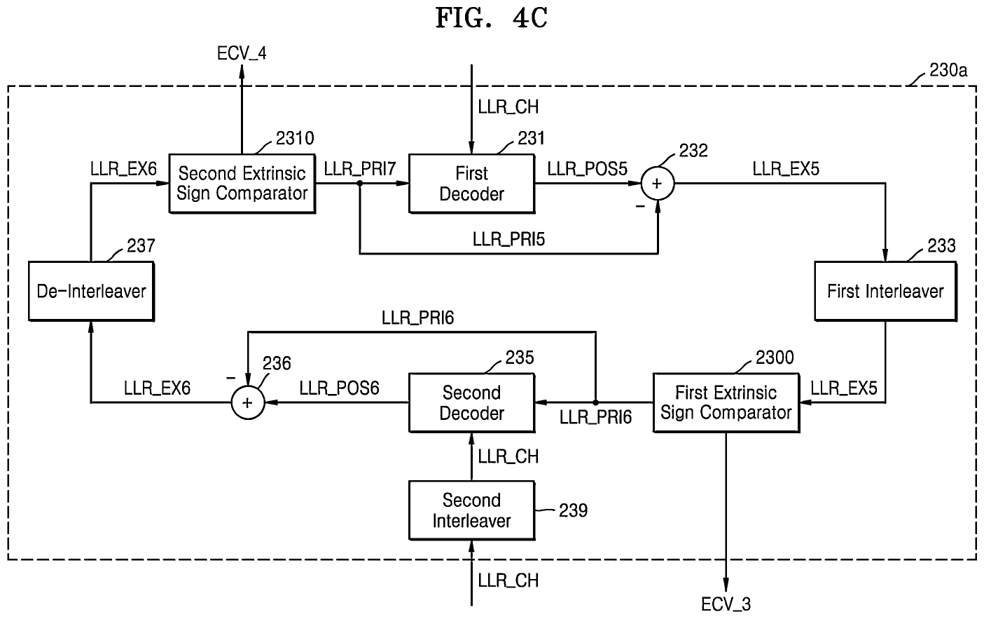

The turbo decoder 230 according to the one or more embodiments may receive the plurality of channel LLRs LLR_CH corresponding to the plurality of bits, respectively, from the MIMO demodulator 250 and may generate a plurality of posteriori LLRs corresponding to the plurality of bits, respectively, based on the plurality of channel LLRs LLR_CH. The turbo decoder 230 may generate an extrinsic LLR based on the difference between the posteriori LLR and the priori LLR. Hereinafter, the turbo decoder 230 may adjust the extrinsic LLR. The adjusted extrinsic LLR as the priori LLR may be used to generate the posteriori LLR. The turbo decoder 230 may generate the extrinsic LLR as a soft value. The turbo decoder 230 may generate the plurality of extrinsic LLRs as soft values for the plurality of bits, respectively, included in the code block Specifically, the extrinsic LLR generated in the previous iterative loop for each of the plurality of bits may affect the generation of the extrinsic LLR corresponding to the current iterative loop. More details are described below with reference to FIG. 4A.

When the sign of the extrinsic LLR generated in the N^{th} iterative loop is the same as the sign of the extrinsic LLR generated in the N+1^{th} iterative loop, the receiver 200 may determine that decoding for the corresponding bit is successful. In this case, the receiver 200 may generate an extrinsic LLR by iterating the loop a predetermined number of times and may decode the corresponding bit based on the final extrinsic LLR.

On the other hand, when the sign of the extrinsic LLR generated in the N^{th} iterative loop is different from the sign of the extrinsic LLR generated in the N+1^{th} iterative loop, the receiver 200 may determine that decoding for the corresponding bit is inappropriate. In this case, although the receiver 200 generates the extrinsic LLR by repeating the loop a predetermined number of times, the probability of decoding failure is relatively high. In other words, when the sign of the extrinsic LLR changes as the loop is repeated, that is, when the sign transitions, it is difficult to trust the decoding result.

When the signal to noise ratio (SNR) of the received signals is low, the sign of the extrinsic LLR for each of the plurality of bits included in the corresponding code block may transition, and thus, the probability of decoding failure for the code block may be high. The receiver 200 according to the one or more embodiments may generate a counting value CV by counting the number of bits corresponding to the extrinsic LLR where the sign transitions. When the counting value CV is greater than a predetermined threshold, the receiver 200 may determine that decoding for the code block will fail and may stop decoding early for the plurality of bits included in the code block.

The turbo decoder 230 is described above as generating the counting value CV based on the sign transition of the extrinsic LLR. However, the turbo decoder 230 according to one or more embodiments may generate the counting value CV based on the sign transition of the posteriori LLR. In addition, the turbo decoder 230 according to another embodiment may generate the counting value CV based on the sign transition of the extrinsic LLR and the sign transition of the posteriori LLR.

The turbo decoder 230 according to the one or more embodiments may provide the counting value CV to the processor 280. The processor 280 according to the one or more embodiments may generate an early stop signal SC to stop decoding of the turbo decoder 230 early based on the counting value CV. The processor 280 may generate the early stop signal SC by comparing the counting value CV with a predetermined threshold. The threshold may be determined based on the number of bits or the counting value CV generated in the previous iterative loop. For example, the threshold may be less than the number of bits. Additionally, the threshold may be less than the counting value CV generated in the previous iterative loop. When the counting value CV is greater than the threshold, the processor 280 may generate and output the early stop signal SC to the turbo decoder 230. The turbo decoder 230 may stop the decoding operation early based on the early stop signal SC. As described above, when the number of bits where the sign of the corresponding log likelihood ratio transitions is greater than or equal to the threshold, the receiver 200 may determine that decoding for the corresponding code block has a high probability of failure. Therefore, the receiver 200 may reduce power by stopping decoding early without repeating the loop a predetermined number of times for the corresponding code block based on the early stop signal CS.

In FIG. 3, for convenience of explanation, the processor 280 is shown as being located outside the turbo decoder 230 but is not limited thereto. The processor 280 may be included in the turbo decoder 230. For example, the turbo decoder 230 may include a decoding control circuit capable of performing operations of the processor 280 described above with reference to FIG. 3.

When the decoding of the turbo decoder 230 for the code block stops early, the receiver 200 according to the one or more embodiments may request the transmitter (100 in FIG. 2) to retransmit the corresponding code block. The receiver 200 may perform decoding on the retransmitted code block as described above.

Referring to FIG. 3, for convenience of explanation, each of the aforementioned components is shown as an independent component, but each component may be designed as a circuit on a single chip. In addition, at least some of the components may be included in a modem chip. For example, the components may include a turbo decoding circuit that performs the operation of the turbo decoder 230 described above with reference to FIG. 3 and a decoding control circuit that performs the operation of the processor 280 described above with reference to FIG. 3. As described with reference to FIG. 3, the turbo decoder 230 and the processor 280 are described below on the assumption that the turbo decoder 230 and the processor 280 are independent components. However, as described above, the circuits that perform each operation may be designed on one chip.

FIGS. 4A to 4C are block diagrams of a turbo decoder according to one or more embodiments.

A turbo decoder 230a of FIGS. 4A to 4C may be the turbo decoder 230 described above with reference to FIG. 3, and overlapping descriptions in this regard may be omitted.

Referring to FIGS. 4A to 4C, the turbo decoder 230a may include a first decoder 231, a second decoder 235, a first adder 232, a second adder 236, a first interleaver 233, a second interleaver 239, a first extrinsic sign comparator 2300, a second extrinsic sign comparator 2310, and a de-interleaver 237.

The turbo decoder 230a according to the one or more embodiments may generate an extrinsic LLR by repeating the iterative loop through the operations of the components, which are described below with reference to FIGS. 4A to 4C. FIG. 4A is a diagram explaining the N^{th} iterative loop of the turbo decoder 230a according to the one or more embodiments, FIG. 4B is a diagram explaining the N+1^{th} iterative loop of the turbo decoder 230a according to the one or more embodiments, and FIG. 4C is a diagram explaining the N+2^{th} iterative loop of the turbo decoder 230a according to the one or more embodiments. Since FIGS. 4A to 4C are diagrams of continuous loops, overlapping descriptions given with reference to FIGS. 4A to 4C may be omitted.

Referring to FIGS. 4A to 4C, the turbo decoder 230a may include the first decoder 231 and the second decoder 235. The first decoder 231 and the second decoder 235 may receive channel LLRs LLR_CH. The first decoder 231 and the second decoder 235 may generate posteriori LLRs (e.g., LLR_POS1) corresponding to the plurality of bits, respectively, based on the channel LLRs LLR_CH. The posteriori LLR (e.g., LLR_POS1), which is output from each of the first decoder 231 and the second decoder 235 may be a value representing the error probability of each decoded bit. As shown in FIGS. 4A to 4C, as the loop is repeated, the extrinsic LLRs (e.g., LLR_EX1 and LLR_EX2) generated from the first decoder 231 and the second decoder 235, respectively, may be may be adjusted by each other. Error correction performance may be improved as the posteriori LLRs (e.g., LLR_POS1 and LLR_POS2) and extrinsic LLRs (e.g., LLR_EX1 and LLR_EX2) generated from two different decoders (i.e., the first decoder 231 and the second decoder 235), respectively, are adjusted by each other.

The first decoder 231 and the second decoder 235 may be a soft input soft output (SISO) decoder. For example, referring to FIGS. 4A and 4B, the first decoder 231 may receive a third priori LLR LLR_PRI3 generated based on a second posteriori LLR LLR_POS2, which is a soft value generated from the second decoder 235. In addition, the first decoder 231 may receive the channel LLR LLR_CH corresponding to each of the plurality of bits. The first decoder 231 may generate a third posteriori LLR LLR_POS3, which is a soft value based on the received third priori LLR LLR_PRI3 and channel LLR LLR_CH.

Referring to FIG. 4A, the first adder 232 may receive the first posteriori LLR LLR_POS1 from the first decoder 231 and may receive the first priori LLR LLR_PRI1 from the second extrinsic sign comparator 2310. The first adder 232 may generate the first extrinsic LLR LLR_EX1 corresponding to the difference between the first posteriori LLR LLR_POS1 and the first priori LLR LLR_PRI1. FIG. 4A shows the operations of the turbo decoder 230a in the first iterative loop. Thus, when N is 1, the first priori LLR LLR_PRI1 may be 0 since there is no first priori LLR LLR_PRI1 generated in the previous iterative loop.

The first interleaver 233 may receive the first extrinsic LLR LLR_EX1 from the first adder 232. The first interleaver 233 may interleave the first extrinsic LLR LLR_EX1 to generate the interleaved first extrinsic LLR LLR_EX1. The interleaving may refer to the operation of rearranging bits to enhance immunity to noise. For convenience of explanation, the log likelihood ratio before and after interleaving is equally referred to as the first extrinsic LLR LLR_EX1. However, hereinafter, “extrinsic LLR” is described below on the assumption that the extrinsic LLR is the interleaved first extrinsic LLR LLR_EX1.

The first extrinsic sign comparator 2300 may receive the first extrinsic LLR LLR_EX1. The first extrinsic sign comparator 2300 may adjust the size of the first extrinsic LLR LLR_EX1 to generate a second priori LLR LLR_PRI2. The size of the second priori LLR LLR_PRI2 may be less than the size of the first extrinsic LLR LLR_EX1. The first extrinsic sign comparator 2300 may provide the second priori LLR LLR_PRI2 to the second decoder 235. The second decoder 235 may generate the second posteriori LLR LLR_POS2 based on the second priori LLR LLR_PRI2 generated based on the first posteriori LLR LLR_POS1 generated from the first decoder 231. Thus, as described above, error correction performance may be improved as the posteriori LLRs (or extrinsic LLRs) generated by the two different decoders (i.e., the first decoder 231 and the second decoder 235) are adjusted by each other each other.

The de-interleaver 237 may perform a de-interleaving operation corresponding to the operation of the first interleaver 233 described above. The de-interleaver 237 may generate an extrinsic LLR LLR_EX by performing the de-interleaving operation on the extrinsic LLR LLR_EX.

According to the one or more embodiments, the first extrinsic sign comparator 2300 may store the sign of the first extrinsic LLR LLR_EX1 in addition to adjusting the first extrinsic LLR LLR_EX1. Specifically, the first extrinsic sign comparator 2300 may store the sign of each of the plurality of first extrinsic LLRs LLR_EX1 corresponding to the plurality of bits, respectively, included in the code block. The first extrinsic sign comparator 2300 may compare the sign of the third extrinsic LLR LLR_EX3 generated in the N+1^{th} iterative loop (i.e., next iterative loop) which is described below with reference to FIG. 4B with the sign of the stored first extrinsic LLR LLR_EX1. The first extrinsic sign comparator 2300 may generate a first extrinsic counting value ECV_1 by counting the number of bits, among the plurality of bits, where the sign of the first extrinsic LLR LLR_EX1 is different from the sign of the third extrinsic LLR LLR_EX3. The receiver (e.g., the processor 280 shown in FIG. 3), according to the one or more embodiments, may determine whether to stop decoding early based on a comparison between the first extrinsic counting value ECV_1 and a predetermined first threshold. The first threshold may be determined based on the extrinsic counting value generated in the previous iterative loop or the number of bits.

Referring to the descriptions above and below, the operation of each of the second decoder 235, the second adder 236, the second interleaver 239, and the second extrinsic sign comparator 2310 may be understood through the aforementioned operation of each of the first decoder 231, the first adder 232, and the first interleaver 233. For example, the second extrinsic sign comparator 2310 may store the sign of each of a plurality of second extrinsic LLRs LLR_EX2.

Referring to FIG. 4B, the first decoder 231 may generate a plurality of third posteriori LLRs LLR_POS3 based on the plurality of channel LLRs LLR_CH corresponding to the plurality of bits, respectively, included in the code block and the third priori LLRs LLR_PRI3 corresponding thereto. The first adder 232 may generate a plurality of third extrinsic LLRs LLR_EX3 based on the difference between the plurality of third posteriori LLRs LLR_POS3 and the plurality of third priori LLRs LLR_PRI3.

The first extrinsic sign comparator 2300 according to the one or more embodiments may receive the third extrinsic LLRs LLR_EX3 corresponding to the plurality of bits, respectively. As described above, the first extrinsic sign comparator 2300 may generate the first extrinsic counting value ECV_1 by counting the number of bits, among the plurality of bits, where the sign of the first extrinsic LLR LLR_EX1 is different from the sign of the third extrinsic LLR LLR_EX3. The receiver, according to the one or more embodiments, may determine whether to stop decoding early based on the first extrinsic counting value ECV_1 and the predetermined first threshold. The first threshold may be determined based on an extrinsic counting value generated by the first extrinsic sign comparator 2300 in the previous iterative loop. For example, the first threshold may be equal to or less than the extrinsic counting value generated in the previous iterative loop. In addition, the first threshold may be determined based on the number of bits included in the code block. For example, the first threshold may be less than the number of bits.

FIG. 4B shows the operation of the turbo decoder 230a in the second iterative loop. Thus, when Nis 1, there is no extrinsic counting value generated in the previous iterative loop. Accordingly, the first threshold may be determined based on the number of bits. For example, the first threshold may be determined to be a value equal to or less than half of the number of bits.

The first extrinsic sign comparator 2300 may store the sign of the plurality of third extrinsic LLRs LLR_EX3. In addition, the first extrinsic sign comparator 2300 may adjust the third extrinsic LLR LLR_EX3 to generate a fourth priori LLR LLR_PRI4 less than the third extrinsic LLR LLR_EX3.

Referring to FIG. 4B, similar to the above for the operation of the first extrinsic sign comparator 2300, the second extrinsic sign comparator 2310 according to the one or more embodiments may generate a second extrinsic counting value ECV_2. Specifically, the second extrinsic sign comparator 2310 may generate the second extrinsic counting value ECV_2 by counting the number of bits, among the plurality of bits, where the sign of the second extrinsic LLR LLR_EX2 is different from the sign of the fourth extrinsic LLR LLR_EX4. The receiver, according to the one or more embodiments, may determine whether to early stop decoding of the turbo decoder 230a based on the second extrinsic counting value ECV_2 and a predetermined second threshold. The second threshold may be determined based on an extrinsic counting value generated by the second extrinsic sign comparator 2310 in the previous iterative loop. For example, the second threshold may be less than or equal to the extrinsic counting value generated in the previous iterative loop. In addition, the second threshold may be determined based on the number of bits included in the code block. For example, the second threshold may be less than the number of bits.

FIG. 4B shows the operation of the turbo decoder 230a in the second iterative loop. Similar to the above, when N is 1, there is no extrinsic counting value generated in the previous iterative loop. Therefore, the second threshold may be determined based on the number of bits.

Referring to FIG. 4C, the first decoder 231 may generate a plurality of fifth posteriori LLRs LLR_POS5 based on the plurality of channel LLRs LLR_CH corresponding to the plurality of bits included in a code block and fifth priori LLRs LLR_PRI5 corresponding thereto (see FIG. 4B). The first adder 232 may generate a plurality of fifth extrinsic LLRs LLR_EX5 based on the difference between the plurality of fifth posteriori LLRs LLR_POS5 and the plurality of fifth priori LLRs LLR_PRI5.

The first extrinsic sign comparator 2300 according to the one or more embodiments may receive the fifth extrinsic LLRs LLR_EX5 corresponding to the plurality of bits, respectively. As described above, the first extrinsic sign comparator 2300 may generate a third extrinsic counting value ECV_3 by counting the number of bits, among the plurality of bits, where the sign of the corresponding third extrinsic LLR LLR_EX3 is different from the sign of the corresponding fifth extrinsic LLR LLR_EX5. The receiver, according to the one or more embodiments, may determine whether to early stop decoding of the turbo decoder 230a based on the third extrinsic counting value ECV_3 and a predetermined third threshold. The third threshold may be determined based on an extrinsic counting value (i.e., the first extrinsic counting value) generated by the first extrinsic sign comparator 2300 in the previous iterative loop. For example, the third threshold may be less than or equal to the first extrinsic counting value generated in the previous iterative loop. In addition, the third threshold may be determined based on the number of bits included in the code block.

The first extrinsic sign comparator 2300 may store signs of the plurality of fifth extrinsic LLRs LLR_EX5. In addition, similarly to the above, the first extrinsic sign comparator 2300 may adjust the fifth extrinsic LLR LLR_EX5 to generate a sixth priori LLR LLR_PRI6 less than the fifth extrinsic LLR LLR_EX5.

Referring to FIG. 4C, similar to the above for the operation of the first extrinsic sign comparator 2300, the second extrinsic sign comparator 2310 according to the one or more embodiments may generate a fourth extrinsic counting value ECV_4. Specifically, the second extrinsic sign comparator 2310 may generate a fourth extrinsic counting value ECV_4 by counting the number of bits, among the plurality of bits, where the sign of the corresponding fourth extrinsic LLR LLR_EX4 is different from the sign of the corresponding sixth extrinsic LLR LLR_EX6. The receiver, according to the one or more embodiments, may determine whether to early stop decoding of the turbo decoder 230a based on a comparison between the fourth extrinsic counting value ECV_4 and a predetermined fourth threshold. The fourth threshold may be determined based on an extrinsic counting value (i.e., the second extrinsic counting value) generated by the second extrinsic sign comparator 2310 in the previous iterative loop. For example, the fourth threshold may be less than or equal to the second extrinsic counting value generated in the previous iterative loop. In addition, the fourth threshold may be determined based on the number of bits included in the code block.

The first extrinsic sign comparator 2300 and the second extrinsic sign comparator 2310 are described above with reference to FIGS. 4A to 4B as simultaneously storing and comparing the signs of the extrinsic LLRs and adjusting the extrinsic LLRs, but this is for convenience of explanation and the one or more embodiments is not limited thereto. For example, the first extrinsic sign comparator 2300 and the second extrinsic sign comparator 2310 may refer to a configuration for storing and comparing signs of the extrinsic LLRs, and the turbo decoder 230a may further include a separate configuration for adjusting the extrinsic LLRs.

As described above with reference to FIG. 3, the components included in the turbo decoder 230a may be configured as one circuit and may be referred to as a turbo decoding circuit. In addition, as mentioned above, a person skilled in the art may understand that the turbo decoding circuit and the decoding stop circuit can be implemented on a single modem chip although the decoding stop circuit or the processor (280 in FIG. 3) is not shown in FIGS. 4A to 4C.

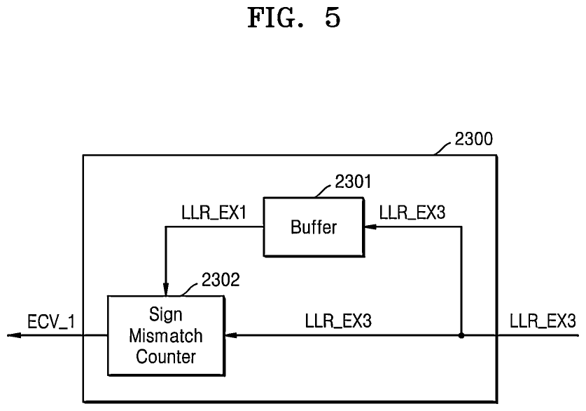

FIG. 5 is a block diagram of an extrinsic sign comparator according to one or more embodiments.

The first extrinsic sign comparator 2300 of FIG. 5 may correspond to the first extrinsic sign comparator 2300 of FIGS. 4A to 4C, and overlapping descriptions are omitted. In addition, the operation of the second extrinsic sign comparator 2310 of FIGS. 4A to 4C, which operates similarly to the first extrinsic sign comparator 2300 of FIG. 5, may be understood through the description below with reference to FIG. 5.

Referring to FIG. 5, the first extrinsic sign comparator 2300 may include a buffer 2301 and a sign mismatch counter 2302.

As described above with reference to FIGS. 4A to 4C, the first extrinsic sign comparator 2300 may store the sign of the first extrinsic LLR LLR_EX1. Specifically, the buffer 2301 included in the first extrinsic sign comparator 2300 may store signs of the plurality of first extrinsic LLRs LLR_EX1 corresponding to the plurality of bits, respectively, included in the code block.

As described above with reference to FIGS. 4A to 4C, the sign mismatch counter 2302 according to the one or more embodiments may generate the first extrinsic counting value ECV_1 based on the sign of the first extrinsic LLR LLR_EX1 and the sign of the third extrinsic LLR LLR_EX3. Specifically, the sign mismatch counter 2302 may generate the first extrinsic counting value ECV_1 by counting the number of bits, among the plurality of bits, where the sign of the first extrinsic LLR LLR_EX1 is different from the sign of the third extrinsic LLR LLR_EX3. The first extrinsic sign comparator 2300 may output the first extrinsic counting value ECV_1 to the processor 280 of FIG. 3.

To compare the sign of the fifth extrinsic LLR (LLR_EX5 of FIG. 4C) generated in a next iterative loop with the sign of the third extrinsic LLR LLR_EX3, the buffer 2301 may store the sign of each of the plurality of third extrinsic LLRs LLR_EX3. For example, the buffer 2301 may store the sign of each of the plurality of third extrinsic LLRs LLR_EX3 instead of the sign of each of the plurality of previously stored first extrinsic LLRs LLR_EX1.

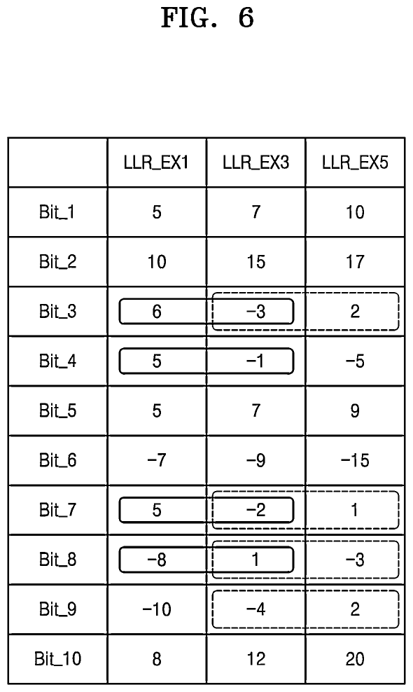

FIG. 6 is a table showing sign transitions of an extrinsic LLR according to one or more embodiments.

FIG. 6 is described below with reference to FIGS. 4A to 4C described above.

FIG. 6 is a diagram to explain the first extrinsic counting value (ECV_1 of FIG. 4B) and the third extrinsic counting value (ECV_3 of FIG. 4C) according to the plurality of first extrinsic LLRs LLR_EX1, the plurality of third extrinsic LLRs LLR_EX3, and the plurality of fifth extrinsic LLRs LLR_EX5 generated through three consecutive iterative loops, according to one or more embodiments.

Referring to FIG. 6, one code block may include 10 bits Bit_1 to Bit_10. The receiver may generate the plurality of first extrinsic LLRs LLR_EX1, the plurality of third extrinsic LLRs LLR_EX3, and the plurality of fifth extrinsic LLRs LLR_EX5 by repeating a iterative loop to construct the code block including 10 bits.

The receiver, according to the one or more embodiments, may count the number of bits in the N+1^{th} iterative loop, among the 10 bits, where the sign of the corresponding first extrinsic LLR LLR_EX1 is different from the sign of the corresponding third extrinsic LLR LLR_EX3. Referring to FIG. 6, the receiver may generate the first extrinsic counting value (ECV_1 of FIG. 4B) by counting the number of bits with different signs of the corresponding extrinsic LLRs, i.e., the third bit Bit_3, the fourth bit Bit_4, the seventh bit Bit_7, and the eighth bit Bit_8. Referring to FIG. 6, the first extrinsic counting value (ECV_1 of FIG. 4B) is 4.

When the first extrinsic counting value (ECV_1 of FIG. 4B) is greater than or equal to the first predetermined threshold, the receiver may early stop decoding of the turbo decoder for the corresponding code block. As described above, the first threshold may be determined based on the number of bits. For example, the first threshold may be determined to be 5 that is less than the number of bits.

When the first extrinsic counting value (ECV_1 of FIG. 4B) is less than the predetermined first threshold, the receiver may generate 10 fifth LLRs LLR_EX5 by performing decoding for the corresponding code block.

The receiver, according to the one or more embodiments, may count the number of bits, among the 10 bits, where the sign of the corresponding third extrinsic LLR LLR_EX3 is different from the sign of the corresponding fifth extrinsic LLR LLR_EX5. Referring to FIG. 6, the receiver may generate the third extrinsic counting value (ECV_3 of FIG. 4C) by counting the number of bits having different signs of the corresponding extrinsic LLRs, that is, the third bit Bit_3, the seventh bit Bit_7, the eighth bit Bit_8, and the ninth bit Bit_9. Referring to FIG. 6, the third extrinsic counting value (ECV_3 of FIG. 4C) is 4.

The receiver may determine whether to stop decoding early based on a comparison between the third extrinsic counting value (ECV_3 of FIG. 4C) and the predetermined second threshold. As described above, the second threshold may be determined based on the first extrinsic counting value (ECV_1 of FIG. 4B), the first threshold, or the number of bits. For example, the second threshold may be determined to be a value equal to or less than the first extrinsic counting value (ECV_1 of FIG. 4B). In addition, the second threshold may be determined to be a value less than the number (e.g., 10) of the plurality of bits. The determined second threshold may be less than the first threshold corresponding to the previous iterative loop.

Referring to FIG. 6, when the second threshold is determined to be less than the first extrinsic counting value (e.g., the second threshold is 3), the receiver, according to the one or more embodiments, may early stop decoding for the code block since the first extrinsic counting value (ECV_1 of FIG. 4B) is the same as the third extrinsic counting value (ECV_3 of FIG. 4C). Accordingly, power consumed in decoding may be reduced by stopping decoding for the code block in which decoding failure is expected.

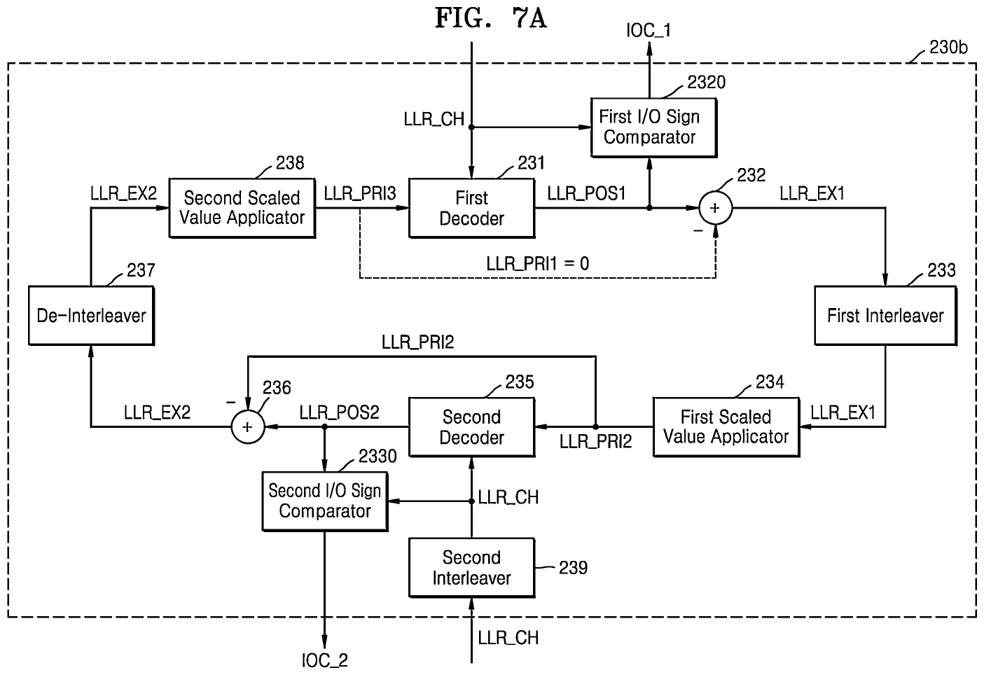

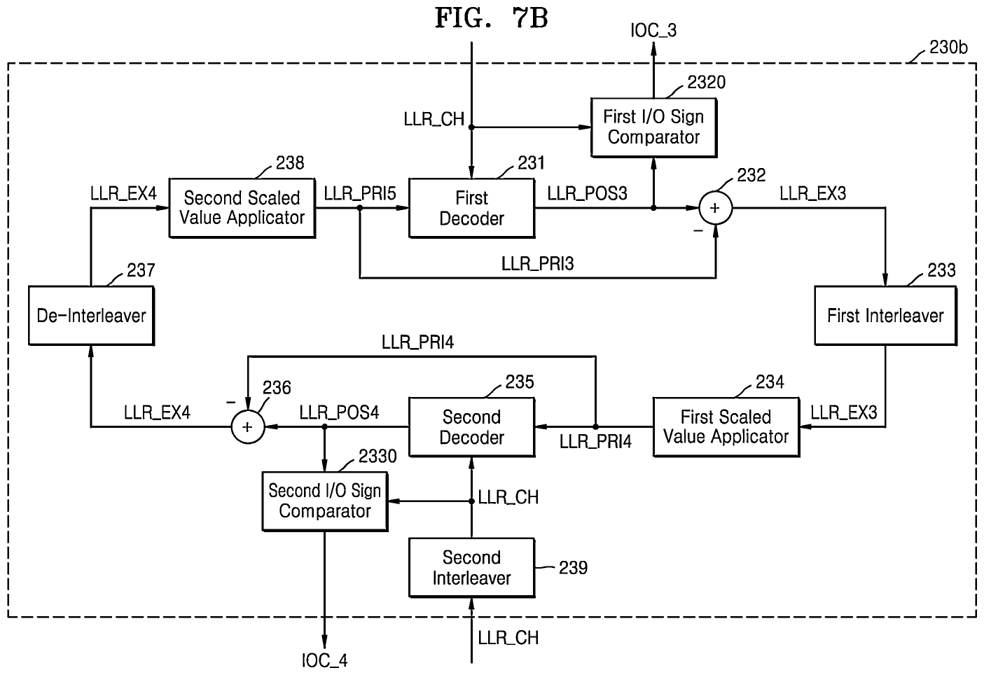

FIGS. 7A and 7B are block diagrams of a turbo decoder according to one or more embodiments.

A turbo decoder 230b of FIGS. 7A and 7B may correspond to the turbo decoder 230 described above with reference to FIG. 3 and may be understood with reference to FIGS. 4A to 4C. Therefore, the overlapping descriptions may be omitted.

Referring to FIGS. 7A and 7B, the turbo decoder 230b may include a first decoder 231, a second decoder 235, a first adder 232, a second adder 236, a first interleaver 233, a second interleaver 239, a first scaled value applicator 234, a second scaled value applicator 238, a de-interleaver 237, a first input/output sign comparator 2320, and a second input/output sign comparator 2330.

The first decoder 231, the second decoder 235, the first adder 232, the second adder 236, the first interleaver 233, the second interleaver 239, and the de-interleaver 237 of FIGS. 7A and 7B which are the same as those of FIGS. 4A to 4C may be omitted.

Each of the first scaled value applicator 234 and the second scaled value applicator 238 may receive an extrinsic LLR and may generate a priori LLR by applying a scaled value to the extrinsic LLR. The scaled value may be a positive real number less than 1 and may be the same value in each of the plurality of iterative loops. However, the one or more embodiments is not limited thereto.

FIG. 7A is a diagram describing an N^{th} iterative loop of the turbo decoder 230b according to the one or more embodiments, and FIG. 7B is a diagram describing an N+1^{th} iterative loop of the turbo decoder 230b according to the one or more embodiments.

Referring to FIG. 7A, the first input/output sign comparator 2320 according to the one or more embodiments may receive the plurality of channel LLRs LLR_CH that are inputs of the first decoder 231 and the plurality of first posteriori LLRs LLR_POS1 that are outputs of the first decoder 231 in the N^{th} iterative loop. The first input/output sign comparator 2320 may generate a first input/output counting value IOC_1 by counting the number of bits, among the plurality of bits, where the sign of the first posteriori LLR LLR_POS1 is different from the sign of the channel LLR LLR_CH.

The receiver, according to the one or more embodiments, may determine whether to stop decoding early based on a comparison between the first input/output counting value IOC_1 and a predetermined fifth threshold. For example, when the first input/output counting value IOC_1 is greater than or equal to the fifth threshold, the receiver may stop decoding early to reduce power consumption. The fifth threshold may be determined based on an input/output counting value generated by the first input/output sign comparator 2320 in the previous iterative loop. For example, the fifth threshold may be less than or equal to the input/output counting value generated in the previous iterative loop. In addition, the fifth threshold may be determined based on the number of bits included in the code block. For example, the fifth threshold may be less than the number of bits.

FIG. 7A shows the operation of the turbo decoder 230b in the first iterative loop. Thus, when N is 1, there is no input/output counting value generated in the previous iterative loop. Accordingly, the fifth threshold may be determined based on the number of bits.

Similar to the above-described first input/output sign comparator 2320, the second input/output sign comparator 2330 may receive the plurality of channel LLRs LLR_CH that are inputs of the second decoder 235 and the plurality of second posteriori LLRs LLR_POS2 that are outputs of the second decoder 235 in the N^{th} iterative loop. The second input/output sign comparator 2330 may generate a second input/output counting value IOC_2 by counting the number of bits, among the plurality of bits, where the sign of the second posteriori LLR LLR_POS2 is different from the sign of the channel LLR LLR_CH.

The receiver, according to the one or more embodiments, may determine whether to stop decoding early based on a comparison between the second input/output counting value IOC_2 and a predetermined sixth threshold. For example, when the second input/output counting value IOC_2 is greater than or equal to the sixth threshold, the receiver may stop decoding early to reduce power consumption. The sixth threshold may be determined based on an input/output counting value generated by the second input/output sign comparator 2330 in the previous iterative loop. For example, the sixth threshold may be equal to or less than the input/output counting value generated in the previous iterative loop. In addition, the sixth threshold may be determined based on the number of bits included in the code block. For example, the sixth threshold may be less than the number of bits.

FIG. 7A shows the operation of the turbo decoder 230b in the first iterative loop. Thus, when N is 1, there is no input/output counting value generated in the previous iterative loop. Accordingly, the sixth threshold may be determined based on the number of bits. The sixth threshold may be the same as the fifth threshold, but this is only an example and the one or more embodiments is not limited thereto.

Referring to FIG. 7B, the first input/output sign comparator 2320 according to the one or more embodiments may receive the plurality of channel LLRs LLR_CH that are inputs of the first decoder 231 and the plurality of third posteriori LLRs LLR_POS3 that are outputs of the first decoder 231 in an N+1^{th} iterative loop. The first input/output sign comparator 2320 may generate a third input/output counting value IOC_3 by counting the number of bits, among the plurality of bits, where the sign of the third posteriori LLR LLR_POS3 is different from the sign of the channel LLR LLR_CH.

The receiver, according to the one or more embodiments, may determine whether to stop decoding early based on the third input/output counting value IOC_3 and a predetermined seventh threshold. For example, when the third input/output counting value IOC_3 is greater than or equal to the seventh threshold, the receiver may stop decoding early to reduce power consumption. The seventh threshold may be determined based on the first input/output counting value IOC_1 and/or the fifth threshold generated by the first input/output sign comparator 2320 in the previous iterative loop. For example, the seventh threshold may be equal to or less than the fifth threshold and the first input/output counting value IOC_1. In addition, the seventh threshold may be determined based on the number of bits included in the code block. For example, the seventh threshold may be less than the number of bits.

The second input/output sign comparator 2330 according to the one or more embodiments may receive the plurality of channel LLRs LLR_CH that are inputs of the second decoder 235 and the plurality of fourth posteriori LLRs LLR_POS4 that are outputs of the second decoder 235 in the N+1^{th} iterative loop. The second input/output sign comparator 2330 may generate a fourth input/output counting value IOC_4 by counting the number of bits, among the plurality of bits, where the sign of the corresponding channel LLR LLR_CH is different from the sign of the corresponding fourth posteriori LLR LLR_POS4.

The operation of the receiver, according to the one or more embodiments, determining whether to stop decoding early based on the fourth input/output counting value IOC_4 and a predetermined eighth threshold may be easily understood through the above description and thus may be omitted. For example, the eighth threshold may be equal to or less than the sixth threshold and the second input/output counting value IOC_2. In addition, the eighth threshold may be determined based on the number of bits included in the code block.

The code block according to one or more embodiments may include a plurality of bits as described above. The plurality of bits may include a plurality of information bits and a plurality of parity bits. The receiver according to one or more embodiments may determine whether to stop decoding early, described above based on the log likelihood ratios for the information bit or the parity bit.

Although not shown in FIGS. 7A and 7B, the first input/output sign comparator 2320 and the second input/output sign comparator 2330 according to the one or more embodiments may include a buffer and a sign mismatch counter which operate similarly to the first extrinsic sign comparator 2300 described above with reference to FIG. 5. For example, the buffer may store a sign of each of the channel LLRs corresponding to the plurality of bits. In addition, the sign mismatch counter may generate input/output counting values by counting the number of bits, among the plurality of bits, where the sign of the corresponding posteriori LLR is different from the sign of the corresponding channel LLR.

As described above with reference to FIG. 3, the components included in the turbo decoder 230b may be integrated into a single circuit which is referred to as a turbo decoding circuit. In addition, although the decoding stop circuit or the processor (280 in FIG. 3) is not shown in FIGS. 7A and 7B, a person skilled in the art may understand that the turbo decoding circuit and the decoding stop circuit can be implemented on a single modem chip, as mentioned above.

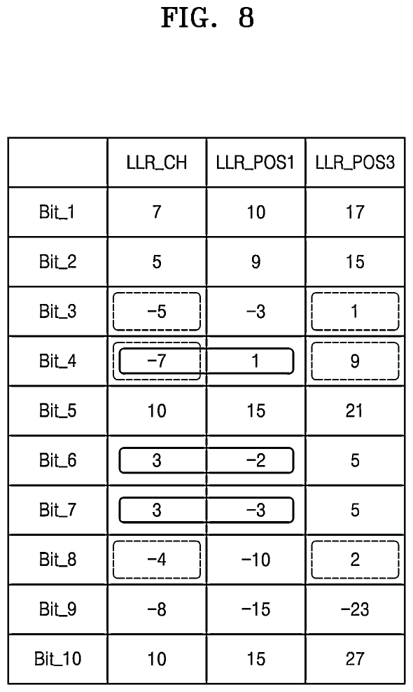

FIG. 8 is a table showing a sign transition of a posteriori LLR with respect to a sign of a channel LLR according to one or more embodiments.

FIG. 8 is described below with reference to FIGS. 7A and 7B described above.

FIG. 8 is a diagram to explain the first input/output counting value IOC_1 of FIG. 7A and the third input/output counting value IOC_3 of FIG. 7B according to the plurality of first posteriori LLRs LLR_POS1 and the plurality of third posteriori LLRs LLR_POS3 generated through two consecutive iterative loops, according to one or more embodiments.

Referring to FIG. 8, one code block may include 10 bits Bit_1 to Bit_10. The receiver, according to the one or more embodiments, may count the number of bits, among the 10 bits, where the sign of the corresponding first posteriori LLR LLR_POS1 is different from the sign of the corresponding channel LLR LLR_CH. Referring to FIG. 8, the receiver may generate the first input/output counting value (IOC_1 of FIG. 7A) by counting the number of bits where the sign of the corresponding first posteriori LLR LLR_POS1 is different from the sign of the corresponding channel LLR LLR_CH, i.e., the fourth bit Bit_4, the sixth bit Bit_6, and the seventh bit Bit_7. Referring to FIG. 8, the first input/output counting value (IOC_1 of FIG. 7A) is 3.

When the first input/output counting value IOC_1 of FIG. 7A is greater than or equal to the predetermined fifth threshold, the receiver may early stop decoding for the corresponding code block. As described above, the fifth threshold may be determined based on the number of bits. For example, the fifth threshold may be determined to be the number (e.g., 10) or less of the plurality of bits.

When the first extrinsic counting value is less than the predetermined fifth threshold (e.g., the fifth threshold is 4), the receiver may perform decoding for the corresponding code block to generate 10 third posteriori LLRs LLR_POS3 corresponding to the 10 bits, respectively.

The receiver, according to the one or more embodiments, may count the number of bits, among the 10 bits, where the sign of the corresponding third posteriori LLR LLR_POS3 is different from the sign of the corresponding channel LLR LLR_CH. Referring to FIG. 8, the receiver may generate the third input/output counting value (IOC_3 of FIG. 7B) by counting the number of bits where the sign of the corresponding third posteriori LLR LLR_POS3 is different from the sign of the corresponding channel LLR LLR_CH, i.e., the third bit Bit_3, the fourth bit Bit_4, and the eighth bit Bit_8. Referring to FIG. 8, the third input/output counting value (IOC_3 of FIG. 7B) is 3.

The receiver may determine whether to stop decoding early based on the third input/output counting value (IOC_3 of FIG. 7B) and the predetermined seventh threshold. As described above, the seventh threshold may be determined based on the first input/output counting value (IOC_1 of FIG. 7A), the fifth threshold, or the number of bits. For example, the seventh threshold may be determined to be a value equal to or less than the first input/output counting value (IOC_1 of FIG. 7A). In addition, the seventh threshold may be determined to be a value less than the number (e.g., 10) of the plurality of bits. The determined seventh threshold may be less than the fifth threshold corresponding to the previous iterative loop. That is, the threshold corresponding to the current iterative loop may be less than the threshold corresponding to the previous iterative loop.

Referring to FIG. 6, when the seventh threshold is determined to be less than the first input/output counting value (e.g., the seventh threshold is 2), the first input/output counting value (IOC_1 of FIG. 7A) and the third input/output counting value (IOC_3 of FIG. 7A) are the same, and thus the receiver, according to the one or more embodiments, may stop decoding early for the code block. Accordingly, power consumed in decoding may be reduced by stopping decoding for the code block where decoding failure is expected.

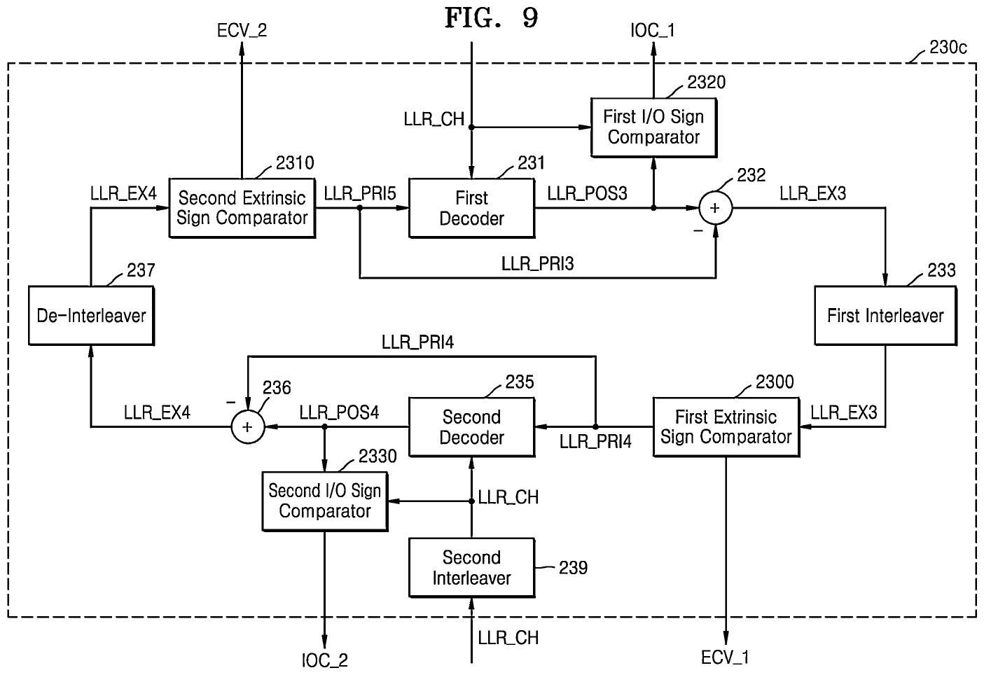

FIG. 9 is a block diagram of a turbo decoder according to one or more embodiments.

A turbo decoder 230c of FIG. 9 may correspond to the turbo decoder 230 described above with reference to FIG. 3 and may be understood with reference to FIGS. 4A to 4C, 7A, and 7B. Therefore, the overlapping descriptions may be omitted.

The turbo decoder 230c of FIG. 9 may generate the extrinsic counting value ECV_1 and/or ECV_2 and the input/output counting value IOC_1 and/or IOC_2. Since the operation of the turbo decoder 230c generating the extrinsic counting value ECV_1 and/or ECV_2 and the input/output counting value IOC_1 and/or IOC_2 may be understood through the above descriptions and thus may be omitted.

It may be understood that the turbo decoder 230c according to the one or more embodiments is combined with the turbo decoder 230a and the turbo decoder 230b described above with reference to FIGS. 4A to 4C, 7A, and 7B. Thus, the receiver including the turbo decoder 230c may compare each of the input/output counting value (e.g., IOC_1) and the extrinsic counting value (e.g., ECV_1) with a predetermined threshold to determine whether to stop decoding early. The threshold compared to each of the input/output counting value (e.g., IOC_1) and the extrinsic counting value (e.g., ECV_1) may be understood through the above descriptions.

In addition, as described above, the components included in the turbo decoder 230c may be configured as a circuit and may be referred to as a turbo decoding circuit. In addition, although the decoding stop circuit or the processor (280 in FIG. 3) is not shown in FIG. 9, a person skilled in the art may understand that the turbo decoding circuit and the decoding stop circuit can be implemented on a single modem chip, as mentioned above.

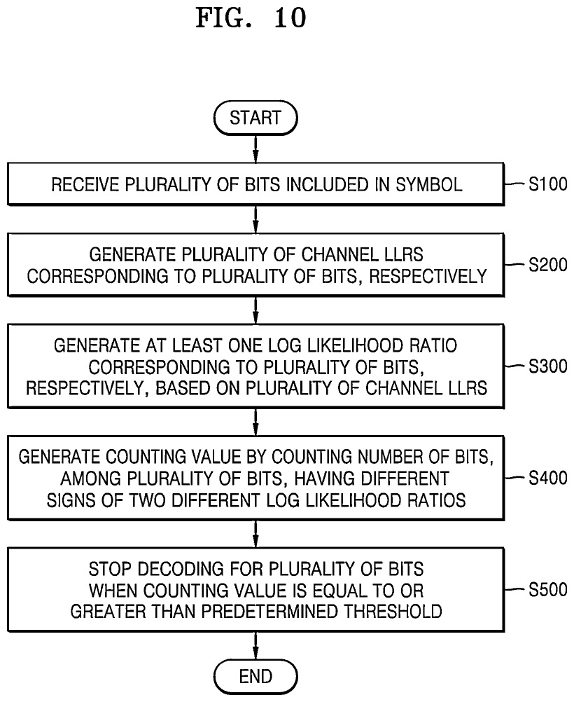

FIG. 10 is a flowchart of an operating method of a turbo decoder according to one or more embodiments.

Referring to FIG. 10, in operation S100, the turbo decoder may receive a plurality of bits included in a symbol.

In operation S200, the turbo decoder may generate a plurality of channel LLRs corresponding to the plurality of bits, respectively.

In operation S300, the turbo decoder may generate at least one log likelihood ratio corresponding to the plurality of bits, respectively, based on the plurality of channel LLRs.

The turbo decoder according to one or more embodiments may generate a plurality of first extrinsic LLRs corresponding to the plurality of bits, respectively, in the N^{th} iterative loop (N is an integer greater than or equal to 1). In addition, a plurality of second extrinsic LLRs corresponding to the plurality of bits, respectively, in the N+1^{th} iterative loop may be generated and a plurality of third extrinsic LLRs corresponding to the plurality of bits, respectively, in the N+2^{th} iterative loop may be further generated.

The turbo decoder, according to another embodiment, may generate a plurality of first posteriori LLRs corresponding to the plurality of bits, respectively, in the N^{th} iterative loop (N is an integer greater than or equal to 1). In addition, a plurality of second posteriori LLRs corresponding to the plurality of bits, respectively, may be generated in the N+1^{th} iterative loop.

In operation S400, the turbo decoder may generate a counting value by counting the number of bits, among the plurality of bits, having different signs of two different log likelihood ratios. The two different log likelihood ratios may include the at least one log likelihood ratio.

The turbo decoder according to one or more embodiments may generate a first extrinsic counting value by counting the number of second extrinsic LLRs, among the plurality of second extrinsic LLRs, having different signs from the corresponding first extrinsic LLRs. In addition, the turbo decoder may further generate a second extrinsic counting value by counting the number of third extrinsic LLRs, among the plurality of third extrinsic LLRs, having different signs from the corresponding second extrinsic LLRs.

The turbo decoder, according to another embodiment, may generate a first input/output counting value by counting the number of first posteriori LLRs, among the plurality of first posteriori LLRs, having different signs from the corresponding channel LLRs. In addition, the turbo decoder may further generate the second input/output counting value by counting the number of second posteriori LLRs, among the plurality of second posteriori LLRs, having different signs from the corresponding channel LLRs.

In operation S500, the turbo decoder may stop decoding for the plurality of bits when the counting value is greater than or equal to a predetermined threshold.

The turbo decoder according to one or more embodiments may stop decoding for the plurality of bits when the first extrinsic counting value is greater than or equal to a first threshold less than the number of bits. In addition, decoding for the plurality of bits may be stopped when the second extrinsic counting value is greater than or equal to the first threshold and the second threshold which is less than the first extrinsic counting value.

The turbo decoder, according to another embodiment, may stop decoding for the plurality of bits when the first input/output counting value is greater than or equal to the first threshold less than the number of bits. In addition, decoding for the plurality of bits may be stopped when the second input/output counting value is greater than or equal to the second threshold which is less than the first threshold and the first input/output counting value.

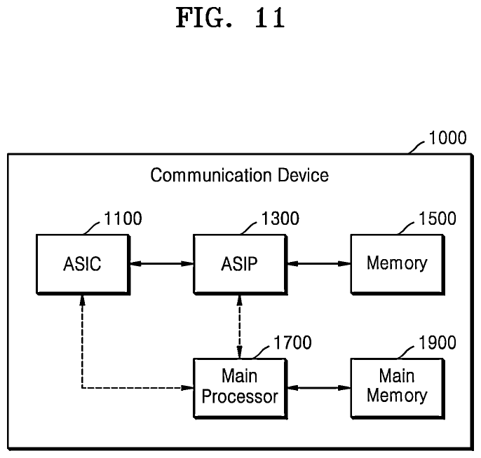

FIG. 11 is a block diagram of a wireless communication device according to one or more embodiments.

Referring to FIG. 11, a wireless communication device 1000, which may correspond to the aforementioned receiver, may include an application specific integrated circuit (ASIC) 1100, an application specific instruction set processor (ASIP) 1300, a memory 1500, a main processor 1700, and main memory 1900. Two or more of the ASIC 1100, the ASIP 1300, and the main processor 1700 may communicate with each other. In addition, at least two or more of the ASIC 1100, ASIP 1300, the memory 1500, the main processor 1700, and the main memory 1900 may be embedded in one chip.

The ASIP 1300 may be a customized integrated circuit for a specific purpose, The ASIP 1300 may support an instruction set for a specific application and may execute instructions included in the instruction set. The memory 1500 may communicate with the ASIP 1300 and may store a plurality of instructions executed by the ASIP 1300 as a non-transitory storage device. For example, the memory 1500 may include, but not limited to, any type of memory accessible by the ASIP 1300, such as random-access memory (RAM), read-only memory (ROM), tape, magnetic disk, optical disk, volatile memory, non-volatile memory, and combinations thereof.

The main processor 1700 may control the wireless communication device 1000 by executing the plurality of instructions. For example, the main processor 1700 may control the ASIC 1100 and the ASIP 1300, process received data, or process the user's input to the wireless communication device 1000. The main memory 1900 may communicate with the main processor 1700 and may store the plurality of instructions executed by the main processor 1700 as a non-transitory storage device. For example, the main memory 1900 may include, but not limited to, any type of memory accessible by the main processor 1700, such as RAM, ROM, tape, magnetic disk, optical disk, volatile memory, non-volatile memory, and combinations thereof.

The main processor 1700 may include the processor 280 described above with reference to FIG. 3, but the one or more embodiments is not limited thereto. The processor (e.g., the processor 280 of FIG. 3) according to the one or more embodiments refers to a configuration for determining whether to stop decoding early based on a counting value.

The wireless communication device and the operating method of the wireless communication device according to one or more embodiments described above with reference to FIGS. 1 to 10 may be performed by at least one of the components included in the wireless communication device 1000 of FIG. 10. In some embodiments, at least one operation of the operating method of the wireless communication device described above may be implemented as the plurality of instructions stored in the memory 1500. In some embodiments, the ASIP 1300 may perform at least one of the operations of the above method by executing the plurality of instructions stored in the memory 1500.

The foregoing exemplary embodiments are merely exemplary and are not to be construed as limiting. The present teaching can be readily applied to other types of apparatuses. Also, the description of the exemplary embodiments is intended to be illustrative, and not to limit the scope of the claims, and many alternatives, modifications, and variations will be apparent to those skilled in the art.

What is claimed is:

1. A modem chip comprising:
a turbo decoding circuit configured to:
receive a plurality of channel log likelihood ratios respectively corresponding to a plurality of bits included in a symbol;
generate a plurality of first posteriori log likelihood ratios respectively corresponding to the plurality of bits in an N^{th} iterative loop based on the plurality of channel log likelihood ratios, wherein N is greater than or equals to 1; and
generate a first input/output counting value by counting a number of first posteriori log likelihood ratios, among the plurality of first posteriori log likelihood ratios, that differ in sign from the corresponding channel log-likelihood ratios; and
a decoding control circuit configured to stop decoding for the plurality of bits in the turbo decoding circuit based on the first input/output counting value being greater than or equal to a first threshold.

2. The modem chip of claim 1, wherein, when the N is 1, the first threshold is determined based on a number of the plurality of bits and is set to be less than a number of the plurality of bits.

3. The modem chip of claim 1, wherein the turbo decoding circuit is further configured to generate a plurality of second posteriori log likelihood ratios respectively corresponding to the plurality of bits in an N+1^{th} iterative loop and generate a second input/output counting value by counting a number of second posteriori log likelihood ratios, among the plurality of second posteriori log likelihood ratios, that differ in sign from the corresponding channel log-likelihood ratios,
wherein the decoding control circuit is further configured to stop decoding in the turbo decoding circuit based on the second input/output counting value being greater than or equal to a second threshold determined based on the first input/output counting value.

4. The modem chip of claim 3, wherein the second threshold is less than the first input/output counting value.

5. The modem chip of claim 3, wherein the second threshold is less than the first threshold.

6. The modem chip of claim 3, wherein the turbo decoding circuit is further configured to generate a plurality of first extrinsic log likelihood ratios respectively corresponding to the plurality of bits based on the plurality of first posteriori log likelihood ratios, generate a plurality of second extrinsic log likelihood ratios respectively corresponding to the plurality of bits based on the plurality of second posteriori log likelihood ratios, and generate a first extrinsic counting value by counting a number of second extrinsic log likelihood ratios, among the plurality of second extrinsic log likelihood ratios, that differ in sign from the corresponding first extrinsic log likelihood ratios,
wherein the decoding control circuit is further configured to stop decoding in the turbo decoding circuit based on the first extrinsic counting value being greater than or equal to a third threshold.

7. The modem chip of claim 6, wherein the turbo decoding circuit is further configured to generate a plurality of third extrinsic log likelihood ratios respectively corresponding to the plurality of bits in an N+2^{th} iterative loop and generate a second extrinsic counting value by counting a number of third extrinsic log likelihood ratios, among the plurality of third extrinsic log likelihood ratios, that differ in sign from the corresponding second extrinsic log likelihood ratios,
wherein the decoding control circuit is further configured to stop decoding in the turbo decoding circuit based on the second extrinsic counting value being greater than or equal to a fourth threshold determined based on the first extrinsic counting value.

8. The modem chip of claim 7, wherein the fourth threshold is less than the first extrinsic counting value.

9. The modem chip of claim 7, wherein the fourth threshold is less than the third threshold.

10. The modem chip of claim 7, wherein a ratio of the first threshold to the second threshold is equal to a ratio of the third threshold to the fourth threshold.

11. A modem chip comprising:
a turbo decoding circuit configured to:
receive a plurality of channel log likelihood ratios respectively corresponding to a plurality of bits included in a symbol;
generate a plurality of first extrinsic log likelihood ratios respectively corresponding to the plurality of bits in an N^{th} iterative loop based on the plurality of channel log likelihood ratios, wherein N is greater than or equals to 1;
generate a plurality of second extrinsic log likelihood ratios respectively corresponding to the plurality of bits in an N+1^{th} iterative loop; and
generate a first extrinsic counting value by counting a number of second extrinsic log likelihood ratios, among the plurality of second extrinsic log likelihood ratios, that differ in sign from the corresponding first extrinsic log likelihood ratios; and
a decoding control circuit configured to stop decoding for the plurality of bits in the turbo decoding circuit based on the first extrinsic counting value being greater than or equal to a first threshold.

12. The modem chip of claim 11, wherein, when the N is 1, the first threshold is determined based on a number of the plurality of bits and is set to be less than a number of the plurality of bits.

13. The modem chip of claim 11, wherein the turbo decoding circuit is further configured to generate a plurality of third extrinsic log likelihood ratios respectively corresponding to the plurality of bits in an N+2^{th} iterative loop and generate a second extrinsic counting value by counting a number of third extrinsic log likelihood ratios, among the plurality of third extrinsic log likelihood ratios, that differ in sign from the corresponding second extrinsic log likelihood ratios,
wherein the decoding control circuit is further configured to stop decoding in the turbo decoding circuit based on the second extrinsic counting value being greater than or equal to a second threshold which is less than the first threshold.

14. The modem chip of claim 13, wherein the second threshold is determined based on the first extrinsic counting value.

15. The modem chip of claim 14, wherein the second threshold is less than the first extrinsic counting value.

16. An operating method of a turbo decoder, the operating method comprising:
receiving a plurality of bits included in a symbol;
generating a plurality of channel log likelihood ratios respectively corresponding to the plurality of bits;
generating at least one log likelihood ratio respectively corresponding to the plurality of bits based on the plurality of channel log likelihood ratios;
generating a counting value by counting a number of bits, among the plurality of bits, where two corresponding log likelihood ratios have different signs; and
stopping decoding for the plurality of bits based on the counting value being greater than or equal to a preset threshold,
wherein the two different log likelihood ratios comprise the at least one log likelihood ratio.

17. The operating method of claim 16, wherein the generating of the at least one log likelihood ratio comprises generating a plurality of first extrinsic log likelihood ratios respectively corresponding to the plurality of bits in an N^{th} iterative and generate a plurality of second extrinsic log likelihood ratios respectively corresponding to the plurality of bits in an N+1^{th} iterative loop,
N is greater than or equals to 1, and
the generating of the counting value comprises generating a first extrinsic counting value by counting a number of second extrinsic log likelihood ratios, among the plurality of second extrinsic log likelihood ratios, that differ in signs from the corresponding first extrinsic log likelihood ratios,
the stopping of the decoding comprises stopping decoding for the plurality of bits based on the first extrinsic counting value being greater than or equal to a first threshold which is less than a number of the plurality of bits.

18. The operating method of claim 17, wherein the generating of the at least one log likelihood ratio further comprises generating a plurality of third extrinsic log likelihood ratios respectively corresponding to the plurality of bits in an N+2^{th} iterative loop,
the generating of the counting value further comprises generating a second extrinsic counting value by counting a number of third extrinsic log likelihood ratios, among the plurality of third extrinsic log likelihood ratios, that differ in sign from the corresponding second extrinsic log likelihood ratios,
the stopping of the decoding further comprises stopping decoding for the plurality of bits based on the second extrinsic counting value being greater than or equal to a second threshold less than the first threshold and the first extrinsic counting value.

19. The operating method of claim 16, wherein the generating of the at least one log likelihood ratio comprises generating a plurality of first posteriori log likelihood ratios respectively corresponding to the plurality of bits in an N^{th} iterative loop,
N is greater than or equals to 1, and
the generating of the counting value comprises generating a first input/output counting value by counting a number of first posteriori log likelihood ratios, among the plurality of first posteriori log likelihood ratios, that differ in signs from the corresponding channel log likelihood ratios,
the stopping of the decoding further comprises stopping decoding for the plurality of bits based on the first input/output counting value being greater than or equal to a first threshold value less than a number of the plurality of bits.

20. The operating method of claim 19, wherein the generating of the at least one log likelihood ratio further comprises generating a plurality of second posteriori log likelihood ratios respectively corresponding to the plurality of bits in an N+1^{th} iterative loop,
the generating of the counting value further comprises generating a second input/output counting value by counting a number of second posteriori log likelihood ratios, among the plurality of second posteriori log likelihood ratios, that differ in signs from the corresponding channel log likelihood ratios,
the stopping of the decoding further comprises stopping decoding for the plurality of bits based on the second input/output counting value being greater than or equal to a second threshold value which is less than the first threshold and the first input/output counting value.
